(19) United States
(12) Patent Application Publication
(10) Pub. No.: US 2015/0372138 A1
(43) Pub. Date: Dec. 24, 2015

(54) GATE CONFIGURATION WITH STRESS IMPACT AMPLIFICATION

(71) Applicant: Chung Yuan Christian University, Chung Li City (TW)

(72) Inventors: Chang-Chun LEE, Chung Li City (TW); Chia-Ping HSIEH, Chung Li City (TW)

(73) Assignee: CHUNG YUAN CHRISTIAN UNIVERSITY, Chung Li City (TW)

(21) Appl. No.: 14/496,418

(22) Filed: Sep. 25, 2014

(30) Foreign Application Priority Data
Jun. 23, 2014 (TW) 103121581

(51) Int. Cl. H01L 29/78; H01L 27/02; H01L 27/088

(52) U.S. Cl. CPC H01L 29/7843; H01L 27/088; H01L 27/0207

(57) ABSTRACT

A gate configuration with stress impact amplification comprises an element activation zone, at least two source/drain electrodes, a first x direction poly configuration, at least two second x direction dummy poly configurations, at least two y direction dummy poly configurations and two gate electrodes. The at least two source/drain electrodes are located on the element activation zone and are paired as top-down sequence. The first x direction poly configuration is located on the element activation zone, divides the element activation zone into two equal zones and separates the at least two source/drain electrodes. The present invention disperses the stress of the contact-etch-stop-layer (CESL) to the y direction dummy poly configurations.

### CROSS-REFERENCE TO RELATED APPLICATION

This application claims priority of application No. 103121581, filed on Jun. 23, 2014 in the Taiwan Intellectual Property Office.

### FIELD OF THE INVENTION

The invention relates to gate configuration, and more particularly to a gate configuration with stress impact amplification.

### BACKGROUND OF THE INVENTION

Utilizing conventional devices with different test patterns to extract the effects, such as ply spacing effects (PSE) and length of diffusion (LOD) effects resulting from intrinsic stress impact, becomes more difficult when complicated processes and various stressors are introduced. Measured electrical data of devices designed for extracting the stress effects on the channel mobility gain are significantly indistinct-able especially when the stress of each individual stressor is differed by 2˜3 orders in magnitude as the weaker ones are often masked by the stronger ones. Hence, the impact levels of stress on boosting or harming the performance of MOS devices resulting from different stressors cannot be easily judged and differentiated.

For example, U.S. Pat. No. 7,601,574 discloses a method for fabricating a stress enhanced MOS transistor. One such method includes the steps of depositing and patterning a layer of sacrificial material to form a dummy gate electrode and replacing the dummy gate electrode with a stressed gate electrode.

Even though these disadvantages of the prior art are known, there have been no acceptable and easy solutions to solve the problem.

### SUMMARY OF THE INVENTION

One objective of the invention is to provide a gate configuration with stress impact amplification. In one embodiment, the gate configuration with stress impact amplification comprises an element activation zone, at least two source/drain electrodes, a first x direction poly configuration, at least two second x direction dummy poly configurations, at least two y direction dummy poly configurations and two gate electrodes.

The at least two source/drain electrodes are located on the element activation zone and are paired in a top-down sequence. The first x direction poly configuration is located on the element activation zone and divides the element activation zone into two equal zones and separates the at least two source/drain electrodes. The at least two second x direction dummy poly configurations are symmetrically located on the two equal zones of the element activation zone and surround the source/drain electrodes. The at least two y direction dummy poly configurations are in pair and non-contactingly located on the top and the lower edges of the element activation zone, which are parallel with the top and the lower edges of the element activation zone. The gate electrodes are located on one of the at least two y direction poly configurations.

In the another embodiment, the gate configuration with stress impact amplification comprises an element activation zone, at least two source/drain electrodes, a first x direction poly configuration, at least two second x direction dummy poly configurations, at least two y direction dummy poly configurations and two gate electrodes.

The at least two source/drain electrodes are located on the element activation zone and are paired in a top-down sequence. The first x direction poly configuration is located on the element activation zone, divides the element activation zone into two equal zones and separates the at least two source/drain electrodes. The at least two second x direction dummy poly configurations are symmetrically located on the left and right edges of the element activation zone, which are parallel with the left and right edges of the element activation zone. The at least two y direction dummy poly configurations are in a pair and non-contactingly located on the top and the lower edges of the element activation zone, which are parallel with the top and the lower edges of the element activation zone. The gate electrodes are located on one of the at least two y direction poly configurations.

In another embodiment, the gate configuration with stress impact amplification comprises two element activation zones, at least four source/drain electrodes, a first x direction poly configuration, at least two second x direction dummy poly configurations, at least two y direction dummy poly configurations and a gate electrode.

The element activation zones are symmetrical and in a top-down sequence, with a gap between the element activation zones. The at least four source/drain electrodes are located on the element activation zone and are paired in a top-down sequence. The first x direction poly configuration is located on the element activation zone, divides the element activation zone into two equal zones and separates the at least two source/drain electrodes. The at least two second x direction dummy poly configurations are symmetrically located on the left and right edges of the element activation zone, which surround the source/drain electrodes. The at least two y direction dummy poly configurations are in pair and non-contactingly located on the top edge of the top element activation zone and the lower edge of the lower element activation zone, which are parallel with the top edge of the top element activation zone and the lower edge of the lower element activation zone. The gate electrode is located on the center of the first x direction poly configuration.

The present invention can disperse the stress of the contact-etch-stop-layer (CESL) to the y direction dummy poly configurations for amplifying and adjusting directional stress of the desired element. So when complicated process and different engineering stress sources are introduced to a desired element, the electron mobility of the desired element is still maintained at a high efficiency level.

### BRIEF DESCRIPTION OF THE DRAWINGS

FIG. 1 is a first embodiment showing the gate configuration with stress impact amplification of the present invention;

FIG. 2 is a second embodiment showing the gate configuration with stress impact amplification of the present invention;

FIG. 3 is a third embodiment showing the gate configuration with stress impact amplification of the present invention;

FIG. 4 is a fourth embodiment showing the gate configuration with stress impact amplification of the present invention;

FIG. 5 is a fifth embodiment showing the gate configuration with stress impact amplification of the present invention;

FIG. 6 is a sixth embodiment showing the gate configuration with stress impact amplification of the present invention;

FIG. 7 is a seventh embodiment showing the gate configuration with stress impact amplification of the present invention;

FIG. 8 is an eighth embodiment showing the gate configuration with stress impact amplification of the present invention; and

FIG. 9 is a ninth embodiment showing the gate configuration with stress impact amplification of the present invention.

### DETAILED DESCRIPTION OF THE INVENTION

In order to describe details of the preferred embodiment of the present invention, description of the structure, and the application as well as the steps are made with reference to the accompanying drawings. It is learned that after the description, any variation, modification or the like to the structure and the steps of the embodiments of the preferred embodiment of the present invention is easily made available to any person skilled in the art. Thus, the following description is only for illustrative purpose only and does not, in any way, try to limit the scope of the present invention.

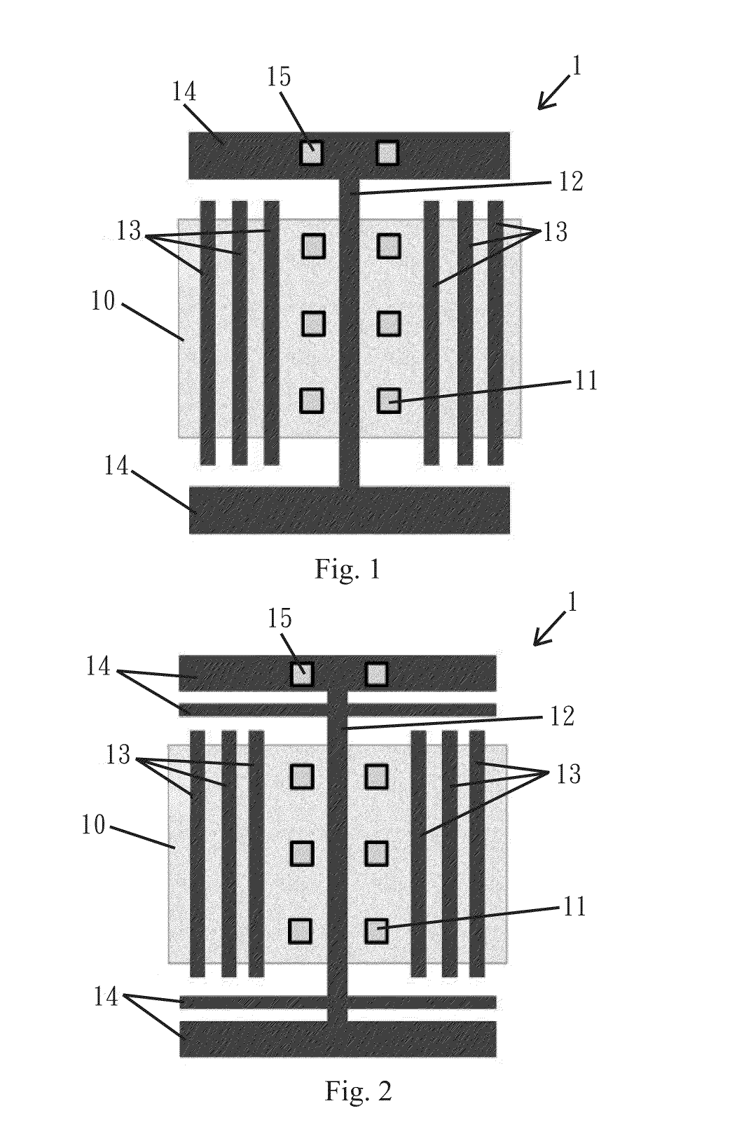

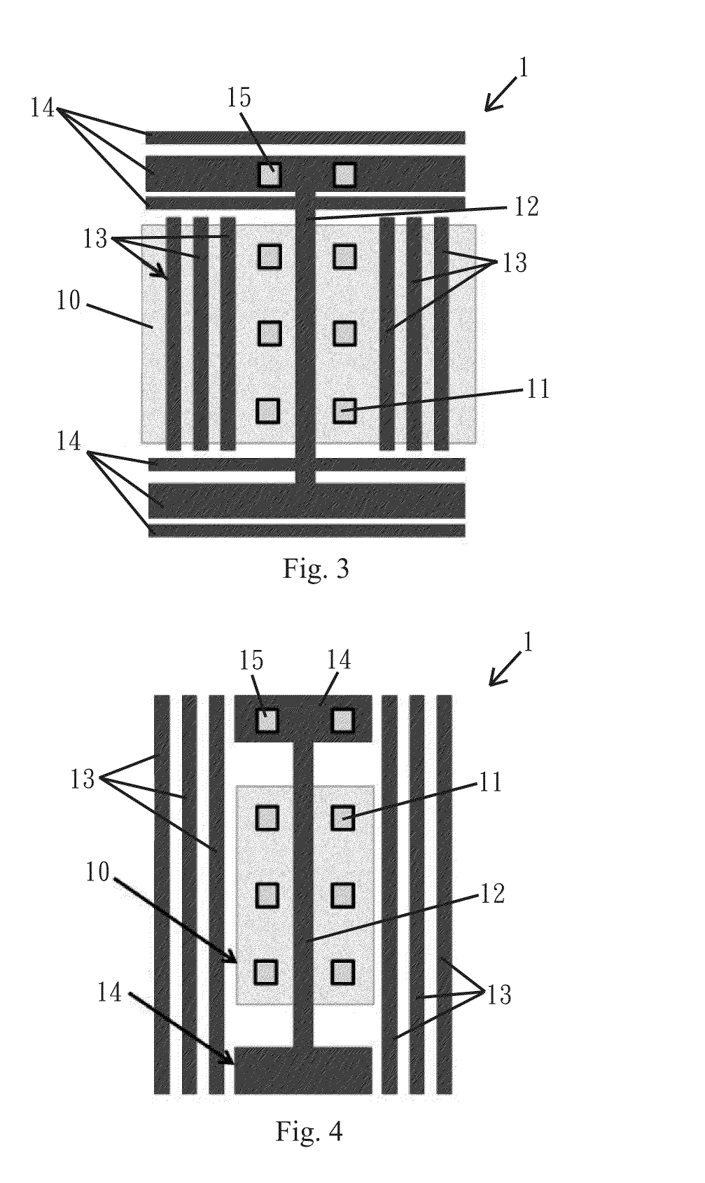

With reference to FIGS. 1 to 3 of the preferred embodiment of the present invention, the gate configuration with stress impact amplification 1 comprises an element activation zone 10, at least two source/drain electrodes 11, a first x direction poly configuration 12, at least two second x direction dummy poly configurations 13, at least two y direction dummy poly configurations 14 and two gate electrodes 15.

The at least two source/drain electrodes 11 are located on the element activation zone 10 and are paired in a top-down sequence.

The first x direction poly configuration 12 is located on the element activation zone 10, divides the element activation zone 10 into two equal zones and separates the at least two source/drain electrodes 11.

The at least two second x direction dummy poly configurations 13 are symmetrically located on the two equal zones of the element activation zone 10 and surround the source/drain electrodes 11.

The at least two y direction dummy poly configurations 14 are in a pair and non-contactingly located on the top and the lower edges of the element activation zone 10, which are parallel with the top and the lower edges of the element activation zone 10.

The gate electrodes 15 are located on one of the at least two y direction poly configurations 14.

Wherein the at least two y direction poly configurations 14 are perpendicular to the first x direction poly configuration 12. Each center of the at least two y direction poly configurations 14 is connected to the two terminals of the first x direction poly configuration 12.

In the two perpendicular edge outside of the element activation zone 10, the length of the at least two y direction poly configurations 14 is extended in a horizontal direction. So the stress influence of the contact-etch-stop-layer (CESL) on a testing element is lower, the stress sensitivity by various stress sources on the element channel length direction lengthways increases dramatically. Besides, using a combination of the at least two y direction poly configurations 14, the first x direction poly configuration 12 and the at least two second x direction dummy poly configurations 13 will further amplify stress influence in the element channel.

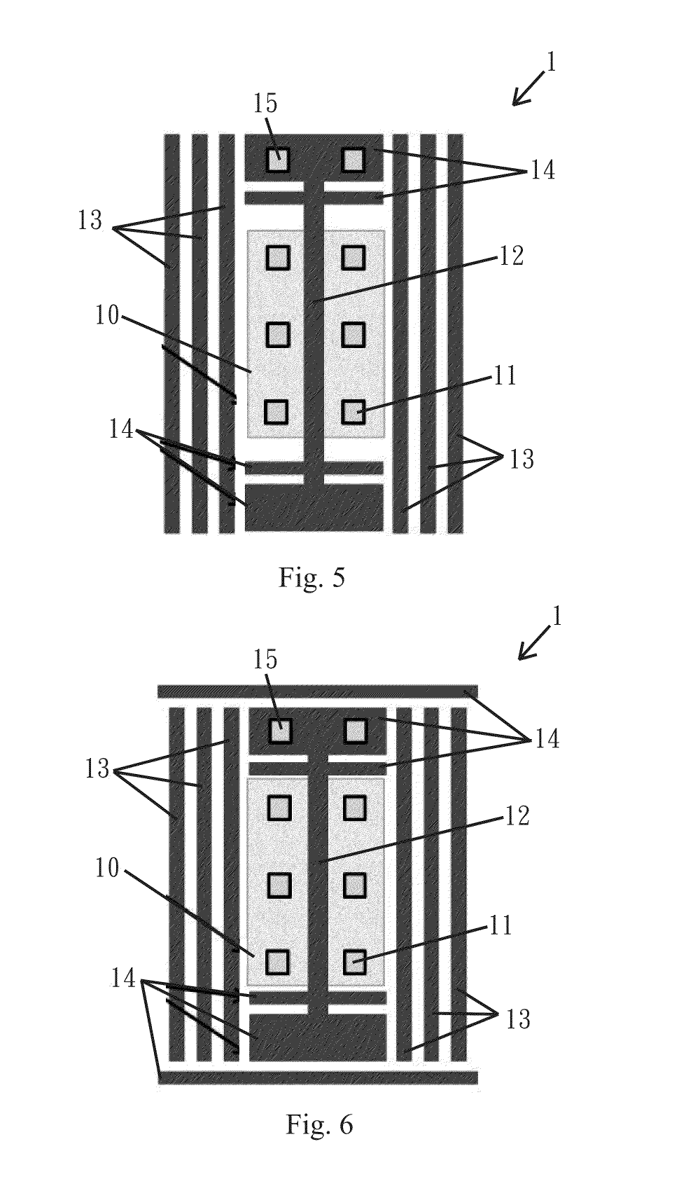

With reference to FIGS. 4 to 6 of the preferred embodiment of the present invention, the gate configuration with stress impact amplification 1 comprises an element activation zone 10, at least two source/drain electrodes 11, a first x direction poly configuration 12, at least two second x direction dummy poly configurations 13, at least two y direction dummy poly configurations 14 and two gate electrodes 15.

The at least two source/drain electrodes 11 are located on the element activation zone 10 and are paired in a top-down sequence.

The first x direction poly configuration 12 is located on the element activation zone 10, divides the element activation zone 10 into two equal zones and separates the at least two source/drain electrodes 11.

The at least two second x direction dummy poly configurations 13 are symmetrically located on the left and right edges of the element activation zone 10, which are parallel with the left and right edges of the element activation zone 10.

The at least two y direction dummy poly configurations 14 are in a pair and non-contactingly located on the top and the lower edges of the element activation zone 10, which are parallel with the top and the lower edges of the element activation zone 10.

The gate electrodes 15 are located on one of the at least two y direction poly configurations 14.

Wherein the at least two y direction poly configurations 14 are perpendicular to the first x direction poly configuration 12, each center of the at least two y direction poly configurations 14 is connected to the two terminals of the first x direction poly configuration 12.

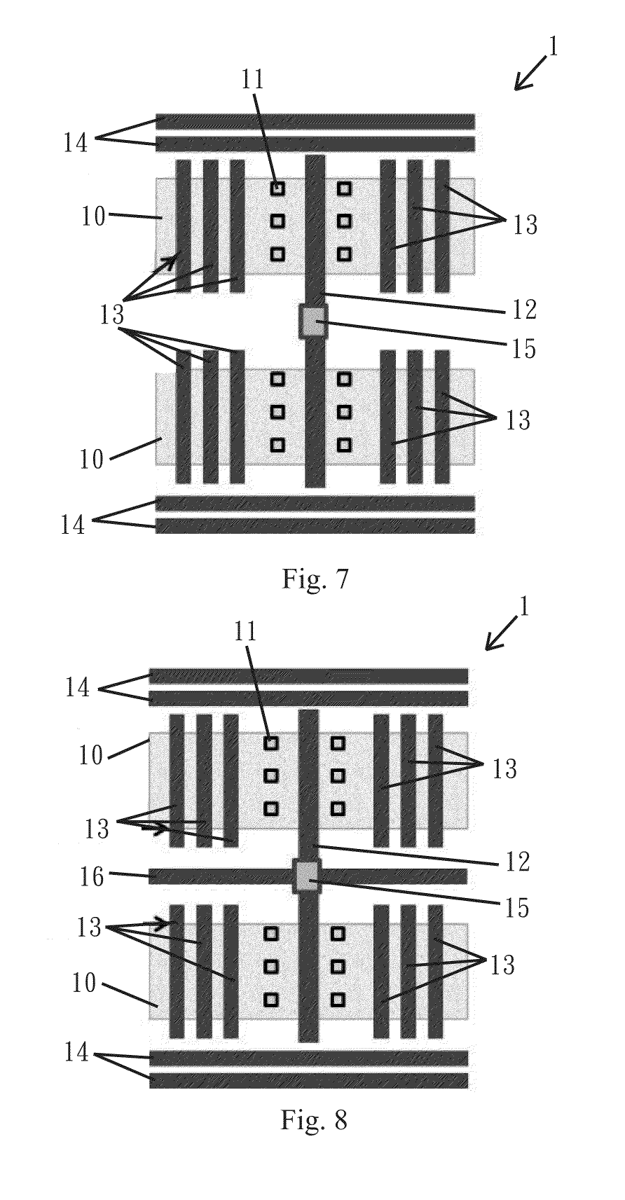

With reference to FIGS. 7 to 9 of the preferred embodiment of the present invention, the gate configuration with stress impact amplification 1 comprises two element activation zones 10, at least four source/drain electrodes 11, a first x direction poly configuration 12, at least two second x direction dummy poly configurations 13, at least two y direction dummy poly configurations 14 and a gate electrode 15.

The element activation zones 10 are symmetrical and in a top-down sequence, with a gap between the element activation zones 10.

The at least four source/drain electrodes 11 are located on the element activation zone 10 and are paired in a top-down sequence.

The first x direction poly configuration 12 is located on the element activation zone 10, divides the element activation zone 10 into two equal zones and separates the at least two source/drain electrodes 11.

The at least two second x direction dummy poly configurations 13 are symmetrically located on the left and right edges of the element activation zone 10, which surrounds the source/drain electrodes 11.

The at least two y direction dummy poly configurations 14 are in a pair and non-contactingly located on the top edge of the top element activation zone 10 and the lower edge of the lower element activation zone 10, which are parallel with the top edge of the top element activation zone 10 and the lower edge of the lower element activation zone 10.

The gate electrode 15 is located on the center of the first x direction poly configuration 12.

In one embodiment, the gate configuration with stress impact amplification 1 further comprises at least one center y direction poly configuration 16 located between the element activation zones 10, and the at least one center y direction poly configuration 16 is parallel with the top edge of the top element activation zone 10 and the lower edge of the lower element activation zone 10.

The y direction poly configuration 14 is perpendicular to the first x direction poly configuration 12.

With reference to FIGS. 1 to 3 and 7 to 9, when the area of the activation zone 10 is smaller, the first x direction poly configuration 12 and the second x direction dummy poly configurations 13 can be surrounded by the y direction dummy poly configurations 14, which are located on laterals of the activation zone 10.

With reference to FIGS. 4 to 6, when the area of the activation zone 10 is bigger, the length of the y direction dummy poly configurations 14 are shortened, and the second x direction dummy poly configurations 13 are extended to the edge of the y direction dummy poly configurations 14 and the activation zone 10.

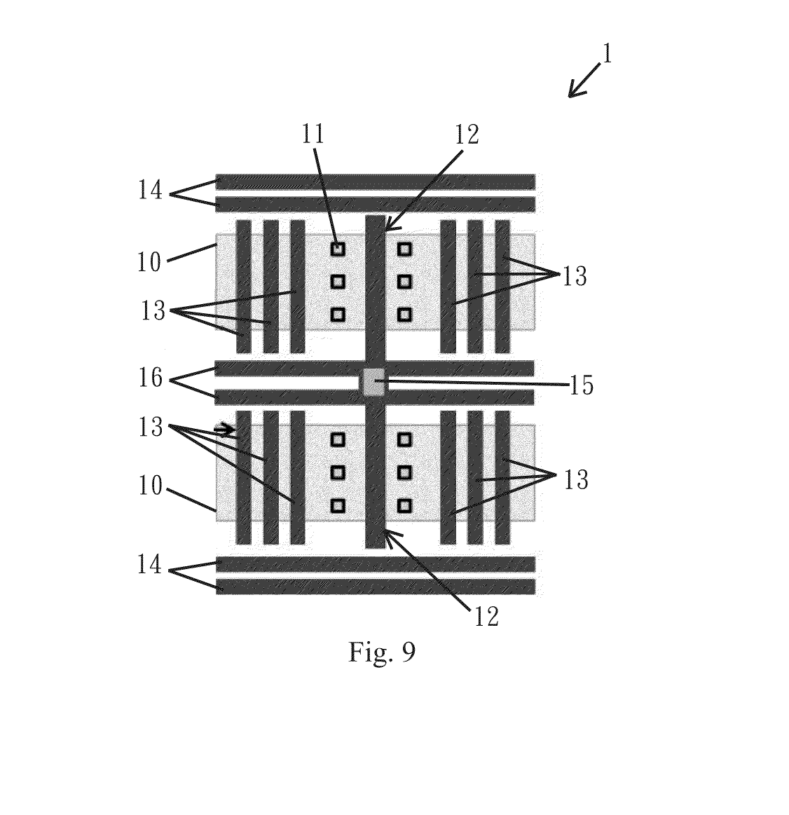

With reference to FIGS. 8 to 9, locating at least one center y direction poly configuration 16 between the element activation zones 10 can reinforce the stress influence of the element activation zones 10 at the same time.

The present invention can disperse the stress of the contact-etch-stop-layer (CESL) to the y direction dummy poly configurations for amplifying and adjusting directional stress of the desired element. So when complicated process and different engineering stress sources are introduced to the desired element, the electron mobility of the desired element is still maintained at a high efficiency level.

While the invention has been described in connection with what is considered the most practical and preferred embodiment, it is understood that this invention is not limited to the disclosed embodiment but is intended to cover various arrangements included within the spirit and scope of the broadest interpretation so as to encompass all such modifications and equivalent arrangements.

What is claimed is:

1. A gate configuration with stress impact amplification comprising:
an element activation zone;
at least two source/drain electrodes located on the element activation zone and paired in a top-down sequence;
a first x direction poly configuration located on the element activation zone, dividing the element activation zone into two equal zones and separating the at least two source/drain electrodes;
at least two second x direction dummy poly configurations symmetrically located on the two equal zones of the element activation zone and surrounding the source/drain electrodes;
at least two y direction dummy poly configurations in a pair and non-contactingly located on the top and the lower edges of the element activation zone, and parallel with the top and the lower edges of the element activation zone; and
two gate electrodes located on one of the at least two y direction poly configurations.

2. The gate configuration with stress impact amplification as claimed in claim 1, wherein the at least two y direction poly configurations are perpendicular to the first x direction poly configuration and each center of the at least two y direction poly configurations is connected to the two terminals of the first x direction poly configuration.

3. A gate configuration with stress impact amplification comprising:
an element activation zone;
at least two source/drain electrodes located on the element activation zone and paired in a top-down sequence;
a first x direction poly configuration located on the element activation zone, dividing the element activation zone into two equal zones and separating the at least two source/drain electrodes;
at least two second x direction dummy poly configurations symmetrically located on the left and right edges of the element activation zone, and parallel with the left and right edges of the element activation zone;
at least two y direction dummy poly configurations in a pair and non-contactingly located on the top and the lower edges of the element activation zone, and parallel with the top and the lower edges of the element activation zone; and
two gate electrodes located on one of the at least two y direction poly configurations.

4. The gate configuration with stress impact amplification as claimed in claim 3, wherein the at least two y direction poly configurations are perpendicular to the first x direction poly configuration, and each center of the at least two y direction poly configurations is connected to the two terminals of the first x direction poly configuration.

5. A gate configuration with stress impact amplification comprising:
two element activation zones in a symmetrical and in a top-down sequence, and having a gap between the element activation zones;
at least four source/drain electrodes located on the element activation zone and paired in a top-down sequence;
a first x direction poly configuration located on the element activation zone, dividing the element activation zone into two equal zones and separating the at least two source/drain electrodes;
at least two second x direction dummy poly configurations symmetrically located on the left and right edges of the element activation zone, and surrounding the source/drain electrodes;
at least two y direction dummy poly configurations in pair and non-contactingly located on the top edge of the top element activation zone and the lower edge of the lower element activation zone, and parallel with the top edge of the top element activation zone and the lower edge of the lower element activation zone; and
a gate electrode located on the center of the first x direction poly configuration.

6. The gate configuration with stress impact amplification as claimed in claim 5, further comprising at least one center y direction poly configuration located between the element activation zones, and the at least one center y direction poly configuration is parallel with the top edge of the top element activation zone and the lower edge of the lower element activation zone.

7. The gate configuration with stress impact amplification as claimed in claim 5, wherein the y direction poly configuration is perpendicular to the first x direction poly configuration.
